(19) United States
(12) Patent Application Publication
(10) Pub. No.: US 2025/0096067 A1
(43) Pub. Date: Mar. 20, 2025

(54) THERMAL BUFFERING ELECTRICAL INTERCONNECTS

(71) Applicant: U.S. Army DEVCOM, Army Research Laboratory, Adelphi, MD (US)

(72) Inventors: Michael C. Fish, Arlington, VA (US); Rachel C. McAfee, Washington, DC (US)

(21) Appl. No.: 18/369,934

(22) Filed: Sep. 19, 2023

(51) Int. Cl. H01L 23/373; H01L 23/495

(52) U.S. Cl. CPC H01L 23/3733; H01L 23/49579

(57) ABSTRACT

We disclose novel thermal buffering electrical interconnects. They are formed of an electrical circuit which generates heat; and a composite electrically connected to the circuit and comprising a porous scaffold having a phase change material (PCM) at least partially filling the porous space of the scaffold jointly capable of carrying an electric current. The PCM-filled porous scaffold is electrically conductive.

### GOVERNMENT INTEREST

The invention described herein may be manufactured, used and licensed by or for the U.S. Government without the payment of royalties thereon.

### BACKGROUND OF THE INVENTION

### Field

Embodiments of the present invention are directed to electrical circuits, and more particularly, to thermal buffering electrical interconnect structures.

### Description of Related Art

Phase change materials (PCMs) have been proposed to manage thermal transients in high-power systems, but they have been previously deployed in energy storage modules located remotely on a cooling loop. This reduces the responsiveness of the PCM, undermining its ability to respond to the high frequency components of a transient loading profile. By placing PCM as close as possible to the devices in question, this responsiveness can be enhanced.

Near-junction deployments of PCMs have also been investigated but have so far required modifying the devices or their substrates (e.g., cutting channels in silicon device backsides, interposing PCM between substrates and module baseplates). Besides their invasive nature, these approaches can accommodate only limited volumes of the PCM, limiting the amount of thermal energy that can be stored. They also tend to be placed in the path of primary heatflow for heat leaving the devices to the steady solution (e.g., heatsink), sabotaging the steady state thermal performance of the system as a result of the low PCM thermal conductivity compared to state of the art (SOA) packaging materials.

Improvements are desired.

### BRIEF SUMMARY OF THE INVENTION

Embodiments of the present invention are directed to novel thermal buffering electrical interconnects. For instance, according to an embodiment, a thermal buffering electrical interconnect comprises: an electrical circuit which generates heat; and a composite electrically connected to the circuit and comprising a porous scaffold having a phase change material (PCM) at least partially filling the porous space of the scaffold jointly capable of carrying an electric current. The PCM-filled porous scaffold is electrically conductive.

The circuit can include an integrated circuit, a laser diode module or a power electronic module. The interconnects may be configured for single-use storage, buffering or failsafe applications. For buffering and failsafe applications, the melting point of the PCM may be selected to be below the maximum safe operating temperature of the circuit; the melting point of the PCM may be about 5-20° C. less than the maximum safe operating temperature of the circuit, as an example. For single-use storage applications, the melting point of the PCM may be selected to be above the initial starting temperature of the circuit but below the maximum operating temperature of the circuit.

In some embodiments, the electrical interconnect can further comprise a wetting layer formed on the surface of the circuit which is contact with to the PCM-filled porous scaffold. The electrical interconnect can further comprise a compliant dielectric material encapsulating the circuit and the PCM-filled porous scaffold. The compliant dielectric material may be a silicone gel or lacquer, for instance.

The porous scaffold could be an open pore foam, sponge, woolen material, or 3D printed open pore scaffolding. For example, the unfilled porous scaffold has a porosity of about 75-97% or more and an average pore size of approximately 0.01-2.5 mm, and the unfilled porous scaffold has a surface density of about 350-1500 g/m². The unfilled porous scaffold may be a metal or alloy, carbon-based material, or ceramic material. For example, the metal or metal alloy scaffold can be formed of nickel (Ni), aluminum (Al), copper (Cu) or carbon (C), as non-limiting examples. The phase change material may comprise a metal or metal alloy, wax or sugar alcohol. For instance, the metal or metal alloy PCM may be gallium (Ga), indium (In), tin (Sn), bismuth (Bi), cadmium (Cd), lead (Pb), zinc (Zn) or antimony (Sb). The electrical conductivity of the PCM-filled porous scaffold is 1-1000 S/cm or more.

The electrical interconnect may further include electrical contacts/electrodes, such as a first electrode contact electrically connected to the circuit; and a second electrode contact electrically connected to the PCM-filled porous scaffold. Electrically conductive wires or traces can connect to the electrode contacts.

According to another embodiment, a thermal buffering electrical interconnect comprises: a first electrode contact; an electrical circuit which generates heat electrically connected to the first contact; a composite electrically connected to the circuit and comprising an electrically conductive porous scaffold having an electrically conductive phase change material (PCM) at least partially filling the porous space of the scaffold, wherein the melting point of the metal PCM is selected to be below the maximum safe operating temperature of the circuit; and a second electrode contact electrically connected to the metal-filled porous scaffold.

These and other embodiments of the invention are described in more detail, below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments, including less effective but also less expensive embodiments which for some applications may be preferred when funds are limited. These embodiments are intended to be included within the following description and protected by the accompanying claims.

FIG. 1 is a schematic illustration of a novel thermal buffering electrical interconnect formed of a porous scaffold filled with a PCM according to embodiments of the present invention.

FIG. 2A is a photograph showing a magnified sample of foam. FIG. 2B is a photograph showing a sample of the foam after being infiltrated with metal.

FIG. 3A depicts a laser diode module including thermal buffering electrical interconnect according to an embodiment. FIGS. 3B and 3C are plots demonstrating the near-junction thermal buffering of the laser diode module of FIG. 3A in one particular test.

FIG. 4 depicts a power electronic module including thermal buffering electrical interconnect according to an embodiment.

### DETAILED DESCRIPTION

Embodiments of the present invention provide near-junction thermal buffering interconnects for electronic devices. The novel thermal buffering electrical interconnects create a multifunctional electrical/thermal interconnect structure that can replace traditional wirebonds found in many such devices. More, thermal buffering via thermal energy storage is provided. Thermal energy storage can improve the performance of logic devices during “computational sprints.” In power electronic applications, electric vehicle power converters and battery chargers experience intermittent operation at very high loads and can benefit from thermal load leveling provided by thermal buffers. Solid state circuit breakers generate significant heat during very brief operation and are limited by the ability to instantaneously accommodate that heat. Thermal storage can decouple the relationship between peak power operation and peak thermal rejection.

The thermal buffering electrical interconnects are relevant to any electronic system with significant intermittent power dissipation that results in challenging temperature excursions. The intermittent event could be a one-time occurrence (e.g., failure protection, expendable/attritable systems) where the thermal buffering electrical interconnects can extend the device's or system's ability to accommodate higher power or longer duration events without increasing system size. Some high-power microwave (HPM) systems operate in this fashion. The event could also be cyclic or reoccurring, where the novel thermal buffering electrical interconnects can store and release thermal energy, load-leveling the power that must be handled by the steady cooling solution (radiators, refrigeration loops) and damping transient temperature excursions. In seeking to avoid an over-temperature occurrence, this damping would allow the steady solution to be reduced in size, weight and power (SWaP), allowing the average temperature to rise by an amount equivalent to cyclic amplitude damping achieved by the PCM. Such cyclic loadings can be highly prescribed such as high energy lasers, or stochastic such as in traction drives on electrified vehicles driving on rough or hilly terrain. Near-junction deployment of PCMs, as in embodiments of this invention, raises the upper limit of frequencies that can be addressed through phase change energy storage. Specifically, we rely upon PCMs which undergo a solid-liquid (S-L) phase change upon melting.

A key aspect of this invention is the use of a PCM infiltrated into a porous scaffold which form a composite having a bulk electrical conductivity that provides an electrical interconnect capable of providing a thermal buffering functionality co-located with highly dissipating electronic devices.

The composite effectively forms a PCM “joint” which creates intimate electrical and thermal contact with metallized circuits (e.g., chip pads or surfaces) in a similar fashion to solder or sintered bonds. This “joint” is the first PCM to melt upon device heating, providing immediate strain relief and isolating the device from any further mechanical stresses stemming from PCM transition in the composite buffer. By using a porous scaffold filled with a PCM, the surface tension thereof, when in a liquid state, is sufficient to retain the PCM within the confines of the porous scaffold, facilitating integration into an electronic package without rigid containment.

The PCM-filled porous scaffold provides three important functions:

(1) It confines the PCM when in a liquid state (through the PCM's high surface tension) to the outlines of the porous scaffold, which can be cut or shaped into various geometries as required to establish an operational electronic circuit. The greatly facilitates PCM integration, as stray PCM could otherwise create shorts or adverse material interactions.

(2) It enhances the effective thermal conductivity of the PCM/scaffold composite when the scaffold material choice has a thermal conductivity much higher than that of the PCM. (Note: copper is an exemplar of this relatively high thermal conductivity, at 380-400 W/m-K, while low-melting point metal PCMs are generally between 15 and 60 W/m-K.).

(3) It provides a significant increase in PCM surface contact area, by providing porosity, which can mitigate liquid supercooling in susceptible PCMs by creating a multitude of solid phase nucleation sites.

The PCM provides to the composite significant thermal capacitance through its ability to melt and absorb heat dissipated by nearby electronic devices without a corresponding temperature rise. Because of the melting of the PCM, heat is absorbed by the PCM (i.e., when the phase changes from solid to liquid). This reduces the waste heat that would ordinarily be rejected (i.e., to the ambient environment). Thus, this absorbed heat does not require (or at least reduces the amount) of external cooling provided to the system. The thermal capacitance Cₜₕₑᵣₘₐₗ is given by the product of the PCM's (gravimetric) latent heat of melting Hₛₗ and its density ρ, as follows:

$${C}_{thermal} = ρ {H}_{sl} \qquad ( 1 )$$

In SI units, Cₜₕₑᵣₘₐₗ in generally given in units of J/cm³. Thus, for a given heat load (e.g., in Joules), one can calculate the corresponding volume of the PCM V_{req} based on the stored energy E_{storage} as follows:

$${V}_{req} = \frac{{E}_{storage}}{ρ {H}_{sl}} \qquad ( 2 )$$

In its liquid state, the PCM is also able to accommodate arbitrarily high shear strain. As such the porous scaffold may be joined to high-power circuits and devices using the PCM itself rather than a rigid attach using solder or ultrasonic welding. As the PCM begins to melt that attach layer will liquify first, shielding the device from further stresses generated through phase change volume change and/or differential thermal expansion. As the compliant liquid attach may be metallic, it will still maintain sufficient electrical conductivity for high-power device operation. After a transient event concludes and device dissipation decreases to pre-event levels, the standard thermal management approaches (e.g., heat sinks, coldplates, etc.) can draw the excess stored heat out of the PCM, resolidifying it and readying the buffer for the next transient.

Finally, embodiments of the invention may further include encapsulating the PCM/scaffold interconnect and devices with a flexible and compliant dielectric encapsulant material, such as a silicone gel. This dielectric encapsulant insulates devices/interconnects and allows the module to operate at higher blocking voltages without internal arcing. Moreover, the dielectric encapsulant acts as a mechanical adhesive, the PCM/scaffold composited can be kept in place while “floating” on its liquid metal attach while the encapsulant accommodates any small displacements needed by melting/solidifying PCM.

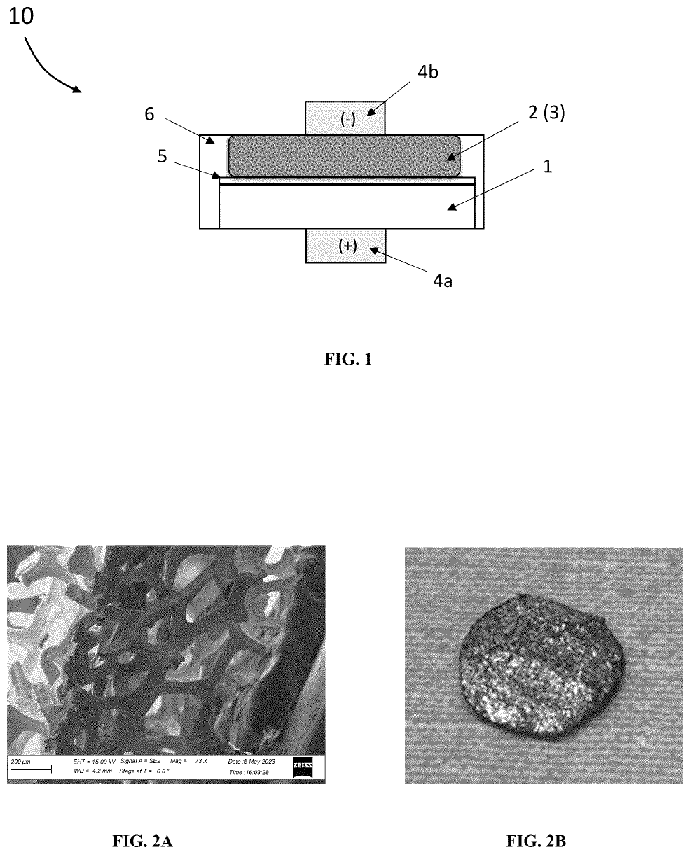

FIG. 1 is a schematic illustration of a novel thermal buffering electrical interconnect 10 formed of a porous scaffold filled with a PCM according to embodiments of the present invention. The thermal buffering electrical interconnect 10 is generally comprised of a circuit 1, a composite 2 (3) formed of a porous electrically conductive scaffold 2 and an electrically conductive phase change material (PCM) 3 at least partially filling the porous space of the scaffold; and one or more electrode contact(s) 4.

The PCM 3 infiltrates the porous scaffold 2 forming a composite 2 (3). The composite 2 (3) thus formed has high bulk electrical conductivity and has superlative thermal buffering properties while the PCM is undergoing a phase transition (i.e., melting). By replacing traditional wirebond interconnects with the composite 2 (3), the transient thermal performance of a power electronic device or package can be substantially improved.

In some embodiments, a wetting layer 5 may be provided between the circuit 1 and the composite 2 (3) to create an intimate thermal and electrical contact with the device metallization. Additionally, in some embodiments, an encapsulant material 6 is further provided which seals the materials. We will describe each of these components in more detail.

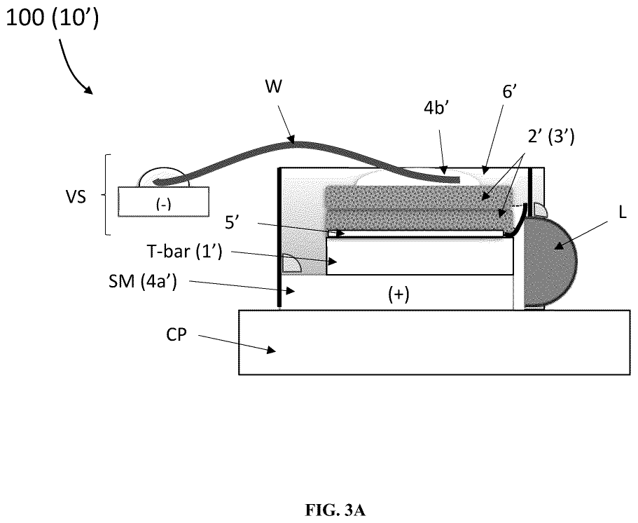

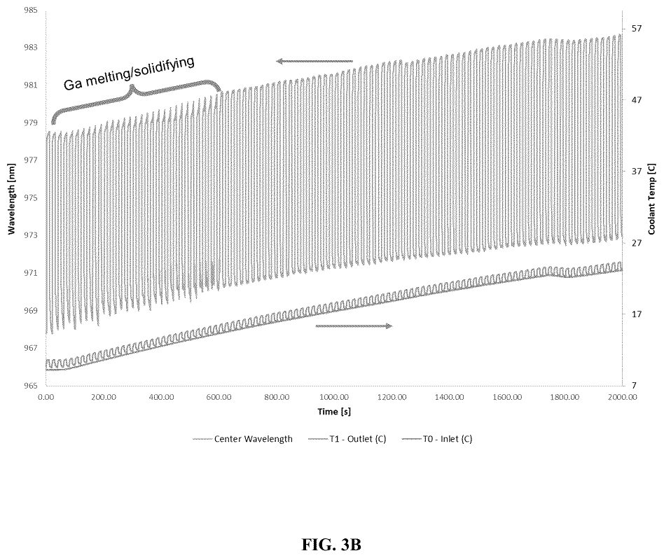

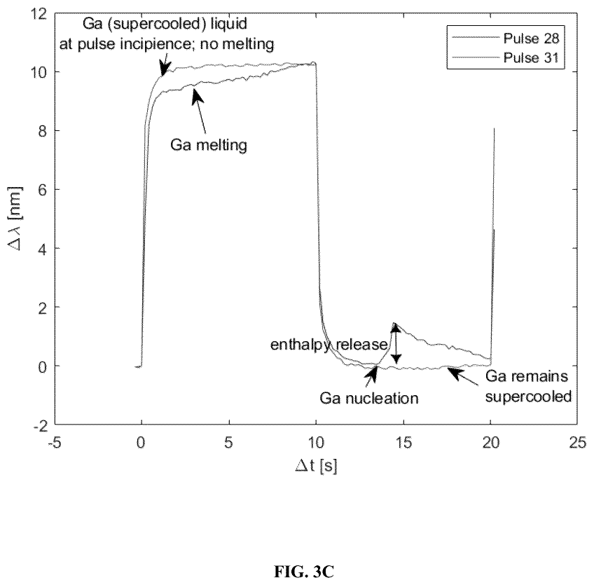

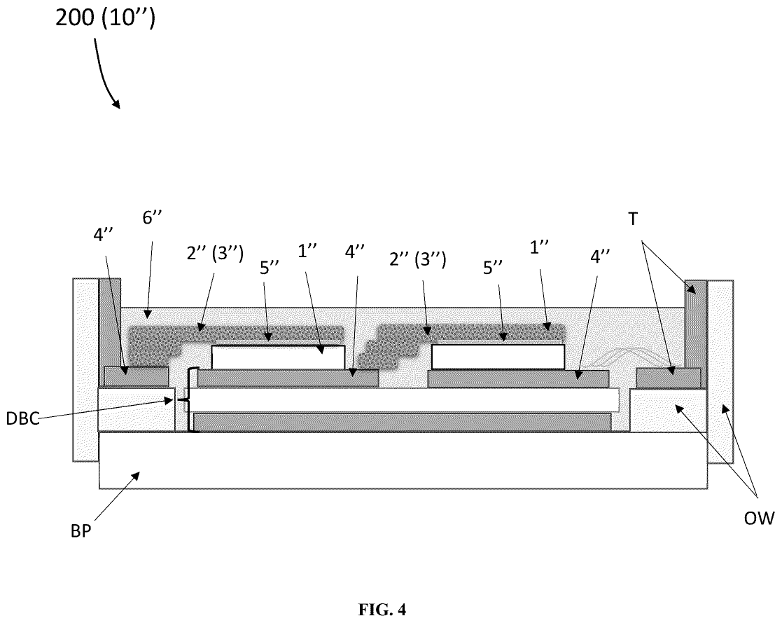

The circuit 1 may be any electrical circuit which generates thermal energy, i.e., waste heat. As those skilled in the art readily understand, heat is primarily generated in circuits where high resistance is found (and esp. where resistive components are concentrated). This is largely present in the vicinity of integrated circuits (ICs), such as “chips” generally formed of semiconductor material, which generate and emit great heat. These can occur in laser diode modules (see FIG. 3A) and power electronic modules (see FIG. 4) as non-limiting examples discussed below.

The composite 2 (3) is formed of the porous scaffold 2 filled with the PCM 3. The PCM 3 is selected to undergo a solid-liquid (S-L) phase change upon melting. Generally, the melting point of the PCM 3 is selected to be above the initial temperature of the circuit 1, but below the safe operating temperature limits of the electronic components.

Moreover, the composite 2 (3) is electrically conductive in the “bulk” sense. Put simply, at least one of the scaffold 2 and the PCM 3 should be electrically conductive, and in some cases, both may be. The term “electrically conductive” as used herein means such conductivity of at least 0.01 S/cm. Preferably, it will be more than 0.1 S/m and more preferably 1-1000 S/cm or even more (e.g., 10⁴-10⁷ S/cm or more). To determine the bulk electrical conductivity of the composite 2 (3), a four-point measurement could be used, for instance; then, the resistance of the interconnect is L/σA where L and A are the length and cross section of the interconnect, resp.

The scaffold 2 may be any material that has a porous structure. In some embodiments, scaffold 2 itself is electrically conductive. To this end, the scaffold 2 may be formed of various metals with high electrical conductivity, such as nickel (Ni), aluminum (Al), copper (Cu), tin (Sn), and/or alloys thereof, as just a few non-limiting examples. Alternatively, the scaffold 2 may be formed of non-metal like conductive carbon (e.g., graphene) and conductive polymer matrix (e.g., polymers with electrically conductive particles like metals/alloys or conductive carbon incorporated therein). Ceramic materials may also be used, such as silicon carbide (SiC).

The scaffold 2 should have “open porosity,” which as used herein means that the pores are open to the ambient and can be infused with a liquid (as opposed to closed cells which are inaccessible to the environment). This permits the scaffold 2 to be filled with the PCM 3 as later discussed. The open porosity may be provided by various materials providing high surface area. This can include various commercially available foam and sponge materials. Porous foam and sponge substrates have a high surface area intrinsically. Also, the scaffold 2 may be a woolen material (e.g., steel wool) which provides a similar open pore structure. It can also include additive manufactured (e.g., 3D printed) open pore scaffoldings. The open pores may be homogenously arranged or randomly spaced. The key parameter is that the pores provide an increased surface area to the scaffold 2 compared to a “flat” surface. Infiltration into arbitrary envelopes could allow novel PCM deployment in configurations not currently possible in the state of the art. Many commercially available foams and sponges have open-cell scaffoldings. They can be fabricated through various means such as blowing air into the molten material as it is solidifying as one example. A sponge is considered a subset of foams that specifically have open porosity. For purposes of this disclosure, the terms open-pore foam and sponge may be used interchangeably.

Surface area has a complicated relationship with porosity. There are multiple measures of high surface area substrates such as surface density (e.g., mass/area or weight/area), porosity (e.g., % of fully dense volume/weight), and surface area density, which is the area contained within a specific volume (e.g., area/volume). For many commercially available open-pore foams and sponges, the degree of porosity may be given in terms of a percentage with a pore size. A higher percentage means greater number of pores compared to the overall size and thus greater surface area. In non-limiting embodiments, the scaffold 2 may range from about 75 to 97%. The average pore diameter can be approximately 0.01-2.5 mm. However, understand there are limits. If, for instance, the porous volume percentage is exceptional high (e.g., approaching 100%), there may be little material left for the scaffold 2 making it mechanically unsound; it could easily crack and break. Pore size or diameter values usually by themselves is not indicative of surface area of the scaffold. Yet, surface area typically increases compared to the overall volume as the pore size decreases (similar to very small particles where the surface area increases compared to volume as the diameter decreases).

Another relevant term is surface density, although, it is not necessarily specific to porous materials. It reports the ratio of the mass (or weight) to the surface area of the scaffolding material. The reciprocal ratio of surface area to mass (or weight) may also be provided in some instances giving the same information. Knowing the mass (or weight) for a given sample, effectively lets one know the surface area. These ratios may be a better criterion for characterizing and selecting a porous surface area for the scaffold 2. The unfilled porous scaffold 2 may have a surface density of about 350-1500 g/m² or more, as a non-limiting example.

Exemplary porous aluminum, zinc, copper and stainless steel open pore foams/sponges are commercially-available, such as the nickel foams from MTI Corporation, at https://www.mtixtl.com/NickelFoamforBatteryCathodeSubstrate1mlength×300mmwidth×1.5mm.aspxo, Duocel® foams from ERG Aerospace, at https://ergaerospace.com/metal-foam-material/, or ceramic foams from ERG Aerospace, at https://ergaerospoace.com/ceramic-/foam!, which may be used for scaffold 2 in non-limiting embodiments.

The thickness of the porous scaffold 2 for the interconnects 10 may be nominally 1.8 mm in some embodiments and implementations. They are commonly available in sheets/panel of about ˜1′×1′ (˜305 mm×305 mm) or 1′×2′ (˜305 mm×610 mm) up to 1-inch (˜305 mm) thick from the manufacturers. Thicker sheets facilitate more volume of phase change material, allowing absorption of more thermal energy which is certainly a useful option. There is, though, a useful upper limit to thickness where un-melted material is simply too far from the heat source to be useful, but this is relative to the power intensity of the heat source and the temperature difference between PCM melting and heat source temperature constraint. Thinner foams can be laminated together, but the discontinuity in the metal matrix could present an additional barrier to heat flow.

The as-sourced foams may be pre-processed before they are filled with the PCM. This may consist of foam cleaning, foam plating, and foam infiltration. Foam cleaning begins with a 1.6 mm thick nickel foam with a pore diameter of 0.25 mm from MTI Corporation. The manufacturer reports a porosity of greater than 95% and an areal density of 346 g/m². Samples may be cut into 8 mm by 20 mm strips, for instance, for infiltration.

FIG. 2A is a photograph showing a magnified sample of MTI Corporation foam having ˜250 μm diameter pores defined by triangular cross section ligaments in an unfilled state (scale 200 μm). The porosity of the foam is clearly visible.

The phase change material (PCM) 3 fills the open pores of the porous scaffold 2. PCMs have attractive thermal properties for thermal buffering of power electronic devices—high thermal conductivity, volumetric latent heat of melting, and transition temperatures below that of power electronic device maximum operating temperatures, for instance. The maximum operating temperature of the circuit can be measured with a thermometer and/or rely on product information provided by a chip manufacturer or vendor. Generally, for Si devices, 125° C. may be assumed for a maximum junction temperature. For SiC devices, 175-225° C. may be typically assumed; although, it depends more on the surrounding materials than the chip itself. One could look to reliability data/testing and decide what an acceptable mean time to failure is and target the corresponding temperature as “safe”. The safe operating temperature to select for the PCM may depend on a number of factors, esp. the power and energies one expects to handle. Nonetheless, as a non-limiting example, it is expected that a PCM with a phase change temperature of about 5-20° C. less than maximum operating temperatures may be an overall good range for many applications and embodiments.

In particular, we consider those which undergo a solid-liquid (S-L) phase change. Such materials may encompass encompasses organic, metallic, and combination PCMs. For sufficient electrical conductivity, as in some embodiments, we mainly have focused on metallic ones herein as non-limiting examples. Non-metallic ones could also be used so long as the resulting composite is electrically conductive and providing PCM at desired temperatures. For instance, waxes (e.g., paraffin) and sugar alcohols (e.g., organic compounds, typically derived from sugars, containing at least one hydroxyl group (—OH) attached to each carbon atom) may be used this purpose.

Electrically conductive PCMs 3 may be an electrically conductive metal or alloy, for instance. The melting point for the metal or alloy should be less than the melting points of materials the scaffold 2. The metal or alloy can either solidify or remain a liquid. So called “low melting point metals (LMPM)” having a melting temperature below 200° C. may be used in some embodiments and implementations.

The melting temperature of the PCMs 3 is selected for the interconnect 10 based on the desired or upper limit operating temperature of the thermal load of the circuit 1 (i.e., semiconductor device formed of say SiC 175C, Si 125C, GaAs or InGaAs) as well as the baseline temperature (usually set by the coolant loop or ambient temperature). The PCMs 3 needs to melt somewhere between the two, with an optimal point that depends on the desired duty cycle of the load. A melt temperature closer to baseline temperature will facilitate heat transfer during melting when there is large driving temperature difference between hot device and melting point of PCM, but will retard the re-solidification during the off state, so is appropriate for low duty cycle. Instead, if the PCM is being used for a failsafe, then melting point should be just above normal operating temperature.

Table I, below, gives the melting temperature (in ° C.) for a few elemental metals which can be used as phase change materials (PCMs) in various embodiments. They include gallium (Ga), indium (In), tin (Sn), bismuth (Bi), cadmium (Cd), lead (Pb), zinc (Zn) and antimony (Sb) as a few non-limiting examples. They are presented in order of increasing melting temperature. Alloys of elemental metals will possess solidus and liquidus temperatures lower than that of their constituents, and at the eutectic ratio of mixing the solidus and liquidus will coincide as a singular melting temperature. For example, eutectic BiInSn has a melting temperature of 59° C.

TABLE I
Melting Points of Some Metal Used as Phase Change Materials (PCMs)

| | | | | Metal | | | | |
|---|---|---|---|---|---|---|---|---|
| | gallium | indium | tin | bismuth | cadmium | lead | zinc | antimony |
| Melting | 29.8 | 156.6 | 231.9 | 271.4 | 321.1 | 327.5 | 419.5 | 630.6 |
| Point (° C.) | | | | | | | | |

The PCMs 3 may be infiltrated into the porous scaffold 2 by various means, such as those for gallium infiltration techniques into nickel foams as discussed in the following paper: M. Fish, A. Wilson, B. Hanrahan and C. Pullen, “Gallium Infiltration of Porous Metal Foams,” 20th IEEE Intersociety Conference on Thermal and Thermomechanical Phenomena in Electronic Systems (iTherm), 2021, pp. 301-307, https://doi.,org/10.1109/ITherm51669.2021.950315, and R. McAfee, M. Fish and H. Tsang, 2023, “Development of Gallium Infiltrated Metal Foams for Transient Thermal Management,” 22nd IEEE Intersociety Conference on Thermal and Thermomechanical Phenomena in Electronic Systems (ITherm). https://ieexplore.ieee.org/abstract/document/10177597, herein incorporated by reference in their entireties.

FIG. 2B is a photograph showing a bulk sample of the nickel foam after having been infiltrated with gallium metal.

Shamberger and Fisher's figure of merit evaluates PCM specific power capacity as follows:

$${η}_{q} = \frac{\sqrt{{k}_{l} \cdot ( ρ {H}_{Δ} )}}{0.775 \sqrt{Δ T}} \qquad ( 3 )$$

Conductivity, density, latent heat, transition temperature, and compatibility all play a key role in PCM material selection in Equation 1. Again, the composite 2 (3) is comprised of the scaffold 2 and the filled PCMs 3. An effective medium analysis can be used to estimate effective thermal conductivity of the composite 2 (3).

We consider the example of porous nickel foam as the porous scaffold 2 and gallium as the filled PCMs 3. The thermal conductivities k for nickel (Ni) is about 90 W/mK at 30° C. and for gallium (Ga) is 29.3 W/mK at 30° C. The rule of mixtures analysis, according to Equation 4, can be used to estimate its effective thermal conductivity in both the liquid and solid phases for the gallium as follows:

$${k}_{eff} = {ϕ}_{Ga} {k}_{Ga} + {ϕ}_{Ni} {k}_{Ni} \qquad ( 4 )$$

A biphasic differential medium approach or effective medium approach, Equations 5 and 6, can also be used to approximate the ideal gallium foam composite as follows:

$$\frac{{k}_{eff} - {k}_{Ga}}{{k}_{Ni} - {k}_{Ga}} {( \frac{{k}_{Ni}}{{k}_{eff}} )}^{1 / 3} = {ϕ}_{Ni} \qquad ( 5 )$$

$${ϕ}_{Ni} \frac{{k}_{Ni} - {k}_{eff}}{{k}_{Ni} + 2 {k}_{eff}} + {ϕ}_{Ga} \frac{{k}_{Ga} - {k}_{eff}}{{k}_{Ga} + 2 {k}_{eff}} = 0 \qquad ( 6 )$$

We note, though, that these equations are somewhat limited in that they do not take surface effects into account. Surface effects such as interfacial resistances between the scaffold and the PCM would reduce effective the bulk conductivity, but the extent to which they exist in and at what length scales they become non-negligible is and active area of research.

Similar equations can be used for other material selections for the composite 2 (3).

There may be any number of electrode contact(s) 4 as may be needed for the particular circuit 1. As shown, two electrode contacts 4a and 4b provide electrically conductive contacts for the interconnect 10. The first and second electrode contacts 4a and 4b may be formed of common solder or braze materials, e.g., lead-tin (PbSn) solders, typical for connecting wires or traces. The connections/attachments from the electrode contacts 4a and 4b to terminals or chips could be rigid (such as via solder/braze/conductive epoxy) or PCM attach (either same as in foam or different depending on mechanical needs).

Ni plated Cu wires are conventionally used for their good solderability. But we also recommend using them to be confident the nickel plating on the copper resists attack from gallium, which tends to be a concern at above 100° C. Available choice of wire would be dictated by the PCM used, although gallium is the most aggressively alloying out of the list above. We note that aluminum wire with gallium would probably be a poor choice for its low resistance to gallium attack. Wires might be dispensed with in some embodiments, such as if the interconnect 10 is directly formed or otherwise integrated into a printed circuit board.

The wetting layer 5 provides for an intimate thermal and electrical contact with the device metallization. It also ensures there are no air pockets trapped between the circuit 1 and the composite 2 (3). The thickness of the layer 5 should be sufficient to accommodate any roughness in the composite/lack of planarity in the composite 2 (3) so it does not scratch the circuit (chip) metallization and compromise any barrier layers (usually chip metal stack is Ti/Ni/Au, and scratching through the Ni could allow Ga to migrate into the semiconductor).

The most straightforward choice for the wetting layer 5 is to use the same material as the PCMs 3, such as, but not limited to, gallium (Ga), indium (In), tin (Sn), bismuth (Bi), cadmium (Cd), lead (Pb), zinc (Zn) and antimony (Sb). One could choose a wetting material that is liquid over a lower temperature range than the bulk of the PCM, so that the interconnect is always “floating.” This, though, may prove challenging in some implementations to prevent undesired alloying and migration between the wetting layer and PCM in the composite. Alternatively, one could solder or braze the composite down with a layer that would always be solid during PCM melting. That could raise concerns with the mechanical stress developed by the volume change of the PCM melting against that joint, but perhaps certain foams or chips would be able to withstand. Other die attach methods may also be relevant and used, including sintered joints and transient liquid phase solders.

In general, the thickness of the wetting layer 5 should be no more than required for intimate contact and adequate protection of the chip metallization. Any thicker and the designer is unnecessarily distancing the usually higher thermal conductivity of the foam from the hot chip, and the thicker free liquid layer is more susceptible to pump out if unencapsulated. That said, the thickness of layer 5 may be in micron range (e.g., up to perhaps 25-100 microns). Although, one could use an excess thickness initially for fabrication purposes. When heated, the excess material of layer 5 can melt into the scaffold 2 and the excess wetting layer 5 material will flow up through the pores and bead on the top, allowing removal as needed.

The encapsulant material 6 can be a potting material is used to sufficiently hold the composite buffer in electrical and thermal contact while being compliant enough to accommodate PCM volume expansion. Various conventional potting materials used in power electronic modules for voltage hold-off can be used for these purposes.

Conventional epoxy overmold of consumer/control electronics and transistor outline (TO) packages could introduce thermal expansion issues without some strain relief component and thus may be avoided. We are thus interested in low hardness to accommodate thermal expansion. For instance, a dielectric gel encapsulant may be used in embodiment, which have Bloom (gel) hardness typically falling between 40 and 200 grams. Traditionally, it is dielectric constant and temperature stability for high voltage power modules that are the primary consideration for gels. The dielectric gel is standard in power electronic (multidie) modules (e.g., >800V). It may be formed of silicone, for example. Common brands include SILGARD™ and DOWSIL™, both from Dow Chemicals. We have successfully used DOWSIL™ 3-4150 Dielectric Gel which is a 2-part room temperature curing gel meaning we can ensure the metal/alloy (such as gallium) is in a solid state during encapsulation.

For low voltage applications, we have found that properly rinsed of HCl residue, the composite can stay on a device with no encapsulation under ambient conditions indefinitely, with only the spring force of the connecting wire holding it in place, although potential for cyclic pump out of the wetting layer and mechanical shock resistance would remain a potential concern. Thus, the gel is a convenient choice given its commercial history, but is a supporting claim, not a critical central component. For voltage hold off one would fully encapsulate all conducting elements. Partial encapsulation (e.g., using lacquer) may be used for low voltage devices that need one portion of the device unobstructed.

In some embodiments, we aim to join chip-to-chip with the composite 2 (3), replacing the stitch bonds like the ones joining chips in many conventional circuits. The circuit 1 and composite 2 (3) and may be fully or partially encapsulated with the encapsulant material 6. The choice may depend on a number of factors, like attachment area and available space in the packaging; thus, there may be tradeoffs.

### Examples

We present two exemplary devices which include a novel thermal buffering electrical interconnect: a laser diode module and a power electronic module.

FIG. 3A depicts a laser diode module 100 including thermal buffering electrical interconnect 10 according to an embodiment.

Multiple laser diode module of this general type form a subunit which is used as a building block (subunit) to modularly scale a laser module in power as described in the following papers: David Irwin, et al., “Narrow-band and low SWaP diodes in tough environments,” SPIE Defense+Security, 2018, Orlando Florida, 1063709; and Andreas Bay, et al., “Scalable and modular diode laser architecture for fiber coupling that combines high-power, high-brightness and low weight,” Proceedings of SPIE—The International Society for Optical Engineering, February 2014, 8965, herein incorporated by reference in their entireties. These circuits generate a lot of heat and use liquid coolant lines to dissipate it.

The laser diode module 100 is formed on a metal baseplate such as solid copper, CuMo or CuW. While not depicted in the figure, there are liquid passages formed in that metal baseplate structure for cooling, hence it is referred to in the art as a “coldplate” CP. The diode circuit 1′ here is known as a “T-bar” which, in the laser diode community, means “tailored bar.” It is a direct bandgap semiconductor junction, such as GaAs, InGaAs, InP, that has been trimmed carefully to create a resonant cavity for laser emission via the laser diode which focuses light via a lens L.

There is a submount SM positioned on the top surface of the coldplate S and below the T-bar (1′) which is a CTE-matched ceramic substrate (such as AlN) that electrically isolates the diode circuit 1′ from the metal coldplate CP. Here, the submount SM forms the positive (+) electrode contact 4a′. A high voltage source 9 connects via wires 7 to the upper electrode 4b′, a negative (−) contact, by a solder material (like PbSn).

In our laser diode module 100 we replace the traditional wirebonds to the diode circuit with the novel thermal buffering electrical interconnect 10′ having a gallium-PCM-infiltrated-nickel foam composite 2′ (3′). The foam 2′ is the same footprint as the diode top-side contact, 4 mm×4 mm, and includes approximately 500 mg of infiltrated gallium PCM 3′ which is equivalent to about 40J of thermal energy storage. To reach this quantity in the available footprint, laminating two foams together using the PCM is required; thicker foam selection would be a preferable alternative. The foam 2′ keeps the gallium 3′ from beading up or migrating from the nickel foam 2′ when in the liquid state, and helps nucleate on cooldown. A metal wetting layer 5′ on the top surface of the T-bar (1′) and the lower surface of the gallium-PCM-infiltrated-nickel foam composite 2′ (3′).

In the conventional T-bar circuit module, the laser diode circuit T-bar (1′) are directly wirebonded to the voltage source via solder. These devices are unencapsulated. The module housing is gasketed and the module is assembled in a clean room. Final housing closure may take place under nitrogen or dry air. By contrast, we encapsulate the T-bar (1′) and composite 2′ (3′) in a flexible encapsulant material 6′ prevents corrosion and provides compliant mechanical adhesion. Rigid containment materials, like epoxy, however, can create undue mechanical stresses unless special efforts are made to accommodate volume changes during melting/solidification. Thus, we use a flexible silicone gel encapsulant 6′, such as DOWSIL™ 3-4150 Dielectric Gel.

FIGS. 3B and 3C are plots demonstrating the near-junction thermal buffering of the laser diode module 100 of FIG. 3A in one particular test. For the laser diode module 100, laser diode output wavelength is linearly related to junction temperature. The upper data line plotted in FIG. 3B shows the diode being pulsed on at full power for 10 seconds and run at very low power for 10 seconds. The coolant being run through the module coldplate starts out at 9.5° C. and is being slowly ramped by a chiller up to 23° C. as demonstrated on the lower data line plotted. The temperature of the diode generally increases and then slowly tapers off. The wavelength X output of the diode relates to temperature. The gallium melts and solidifies early on. However, the coolant temperature increases and eventually exceeds the temperature required for the gallium to re-nucleate.

The plot in FIG. 3C shows more details of the melting/non-melting transition of the gallium. We focused on what happens with two pulses, pulses 28 and 31, which occur at essentially the same conditions, just on opposite sides of the point where the liquid gallium stops re-nucleating. Pulse 28 has water coolant some tenths of a degree cooler than pulse 31, and the supercooling a hallmark of complete melting. The annotations on the plot indicate what is occurring.

The curve for pulse 31 is the time dependent junction temperature without the gallium melting (that is, it is fully liquid the entire time). The mass of the gallium rounds the leading corners of the temperature shifts more than the COTS condition (storing heat as sensible heating). But in curve for pulse 28 the gallium is melting, going from solid to liquid, dramatically suppressing the temperature rise until 10 seconds into the pulse. During the low power segment, the gallium solidifies and rejects the stored latent heat back through the diode, briefly warming it. In fact, this solidification is delayed somewhat because the gallium is supercooling below its transition temperature and abruptly crystallizing about 5 seconds into the low power step.

Earlier in the larger test, as shown on FIG. 3B, supercooling does not occur during the colder coolant temperatures either because the composite is not fully melting during the high power (leaving a solid portion that can serve as a seed during the subsequent re-solidification) or because the re-nucleation is happening so quickly that it is indistinguishable from the sharp drop during the power stepdown. The wavelength difference AX between pulse 28 and 31 implies approximate 7.5% reduction injunction temperature for first several seconds of pulse. This results in a lower peak waste power that must be rejected by the diode coldplate.

FIG. 4 depicts a power electronic module 200 including thermal buffering electrical interconnect 10″ according to an embodiment.

Conventional power electronics modules are formed of many power transistors and diodes. Related transistors and diodes are formed together as “chips” which are wirebonded to each other and voltage source. The wirebonded connections are potted. These conventional wirebond interconnects can be replaced with buffering interconnect possessing appropriate melting temperature. This further enables them to operate as failsafe thermal mitigation or intentional thermal storage for burst operation.

The power electronic module 200 is formed on a metal baseplate BP such as solid copper, CuMo or CuW. In some implementations, there may be a coldplate (not shown) made of Cu or Al located beneath the baseplate BP which has coolant channel to providing cooling.

The outer walls OW may be formed of a dielectric material sized and configured to provide robustness and mechanical stability for the module. The interior may be lined with electrically conductive traces T formed on a metal like copper, for supplying electricity to and from the module 200.

A direct bond copper substrate DBC formed over the baseplate BP. The DBC is a 3-layer sandwich structure. The middle (interior) layer is a ceramic plate, usually AlN, AlO or SiN, isolates the power electronics from the baseplate. The top and bottom layers of the DBC are electrically conductive and formed of a metal, like copper. The top layer of the DBC includes a patterned-etched break which isolates the chips 1″ from one another. Only two chips 1″ are depicted in this figure, although, many more can be present. DBC substrates are typical, but we do not exclude other substrate choices.

Chips 1″ are bonded to DBC with die attach (solder), DBC to baseplate BP with TIM1 (lower temperature solder or epoxy), and baseplate BP to (not shown) coldplate with TIM2 (usually thermal grease). Attach layers are not shown. Those are thermal greased down onto the separate coldplate.

Attached to the top of the chips 1″ are a gallium-PCM-infiltrated-nickel foam composite 2″ (3″). The foam 2″ is optimistically 25% of the headspace volume of the module and includes approximately 100 g of infiltrated PCM 3″ which is equivalent to about 9 kJ of thermal energy storage. The foam 2″ keeps the PCM 3″ from beading up or migrating from the metal foam 2″ when in the liquid state, and helps nucleate on cooldown. A metal wetting layer 5″ on the top surface of the chips 1″ and the lower surface of the PCM-infiltrated-foam composite 2″ (3″). The interconnect and electronics are encapsulated in a flexible silicone gel encapsulant 6″, such as DOWSIL™ 3-4150 Dielectric Gel. Various electrodes 4″ connect to the chips 1″ and the PCM-infiltrated-foam composite 2″ (3″); they may connect via solder.

### Applications

Three example types of applications that influence the choice of melting temperature are single-use storage, buffering, and failsafe applications. In single-use storage, a component to be managed would begin operation at an initial temperature (e.g., 60° C.), rise in temperature during operation and operation must cease when the device reaches a limiting temperature (e.g., 175° C.). In this context, choosing a melting temperature above the initial temperature (with a suitable margin to accommodate incidental shifts in ambient conditions) but below the limit temperature will allow an extension in duration of operation since heat absorbed by the PCM does not contribute to the device temperature rise. Keeping the PCM significantly lower (at say, 80° C.) than the limit temperature will allow stronger heat conduction from the increasingly hotter device to reach more remote PCM material before the limit is reached, increasing the amount of energy stored. In these applications, there is often no other thermal management system beyond the passive thermal capacity of the device and its packaging.

A buffering application is similar to single-use storage in that the PCM transition temperature should be between the low-power steady temperature and the high-power steady temperature, but there is the additional desire to discharge and reject the PCM stored heat during a low-power interval so that its capacity can be reused on the next high-power cycle. This rejection can be to an active thermal management system like a cooling loop, or passively to the ambient environment. If the PCM exhibits hysteresis, supercooling, or off-eutectic solidification such that the solidification temperature is not the same as the melting temperature, the solidification temperature must be above the low-power steady temperature. The constant charging and discharging of the PCM thermal storage will have the effect of damping the temperature excursions experienced by the device during its power cycling. This can be desirable in and of itself because less extreme temperature cycling can reduce mechanical fatigue. It also serves to load-level the heat seen by the thermal management system, reducing the heat rejected during the high-power cycle by the amount stored by the PCM and increasing it by the same amount during the low-power cycle. This can allow the thermal management system to be lightweighted, as it can be sized to handle dissipated power closer to that of the cycle average rather than the peak power dissipated by the chip. The ideal transition temperature of the PCM will be dictated by the duty cycle of the device in addition to the relevant system temperatures—at a 50% duty cycle the transition temperature should be halfway between the intended low- and high-power temperatures.

The third application, failsafe protection, has features drawing from each of the previous two, in that the PCM thermal storage will be used to mitigate a single temperature excursion, but will still be expected to be reusable. The chosen PCM transition temperature will be just above that of the normal operating temperature (with an appropriate margin), but below a critical failure temperature. An example could be a device operating at a refrigerant boiling temperature that might experience thermal runaway in the event of a dryout condition in the coldplate—embodiments of the present invention can mitigate the pace of the resulting temperature rise while allowing flow adjustment or a safe shutdown to occur.

We next present three exemplary use cases for the interconnects configured for single-use storage, buffering and failsafe applications, respectively.

Single-use storage: a single use device delivers a burst of power and accompanying waste heat on a lightweight platform (e.g., distributed sensor). Starting from 25° C., the device's mission terminates when the junction hits 125° C. Setting the PCM melt temperature at 45° C. ensures that it will be ready even on a hot day but is low enough to ensure maximum driving temperature difference as the chip heats up. The thermal capacity from the PCM extends the duration of its mission by a factor (e.g., 4), improving effectiveness.

Buffering: A component with a 50% intermittent cycle lasting 20 seconds on, 20 seconds off is managed by a cooling loop with a compressor running continuously. At the end of its on cycle the component is at its junction limit of 125° C., and at the end of its off cycle the temperature is at 75° C., giving a cycle average temperature of 100° C., rejected using the compressor to a 30° C. ambient. A PCM buffering interconnect is sufficient to damp the amplitude of the thermal cycle from 50K to 25K. A 112.5° C. PCM temperature is selected, so that the cycle moves from 125° C. to 100° C. The larger thermal budget seen by the cooling loop has increased from 70K to 82.5K under the same power conditions, meaning the compressor can likely be sized down.

Failsafe: A traction drive on an electric vehicle is rated for 175° C. junction. As a margin of safety, under normal use its steady temperature is 150° C. (˜80% rated power above a 60° C. coolant loop). Initial temperatures when the vehicle is off are 20-30° C. outdoor temperature. The PCM is selected to melt at 165° C. so that it is ready under most normal use case conditions, but when power surges to 120%, the excursion to a new steady temperature of 200° C. is substantially slower due to the thermal storage of the PCM, and ideally keeps the device below its rated limit for the duration of the surge.

Aspects of this invention have been previously disclosed by the inventors in the following conference paper: Rachel C. McAfee, Michael C. Fish, and Harvey H. Tsang, “Development of Gallium Infiltrated Metal Foams for Transient Thermal Management,” 22nd IEEE Intersociety Conference on Thermal and Thermomechanical Phenomena in Electronic Systems (ITherm), Orlando, FL, 30 May 2023-2 Jun. 2023, herein incorporated by reference in its entirety.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the present disclosure and its practical applications, and to describe the actual partial implementation in the laboratory of the system which was assembled using a combination of existing equipment and equipment that could be readily obtained by the inventors, to thereby enable others skilled in the art to best utilize the invention and various embodiments with various modifications as may be suited to the particular use contemplated.

While the foregoing is directed to embodiments of the present invention, other and further embodiments of the invention may be devised without departing from the basic scope thereof, and the scope thereof is determined by the claims that follow.

We claim:

1. A thermal buffering electrical interconnect comprising:
an electrical circuit which generates heat; and
a composite electrically connected to the circuit and comprising a porous scaffold having a phase change material (PCM) at least partially filling the porous space of the scaffold jointly capable of carrying an electric current,
wherein the PCM-filled porous scaffold is electrically conductive.

2. The electrical interconnect of claim 1, wherein the interconnect is configured for a single-use storage, buffering or failsafe application.

3. The electrical interconnect of claim 2, wherein, for buffering and failsafe applications, the melting point of the PCM is selected to be below the maximum safe operating temperature of the circuit.

4. The electrical interconnect of claim 3, wherein the melting point of the PCM is about 5-20° C. less than the maximum safe operating temperature of the circuit.

5. The electrical interconnect of claim 2, wherein, for single-use storage applications, the melting point of the PCM is selected to be above the initial starting temperature of the circuit but below the maximum operating temperature of the circuit.

6. The electrical interconnect of claim 1, further comprising a wetting layer formed on the surface of the circuit which is contact with to the PCM-filled porous scaffold.

7. The electrical interconnect of claim 1, further comprising a compliant dielectric material encapsulating the circuit and the PCM-filled porous scaffold.

8. The electrical interconnect of claim 7, wherein the compliant dielectric material comprises a silicone gel or lacquer.

9. The electrical interconnect of claim 1, wherein the circuit comprises an integrated circuit, a laser diode module or a power electronic module.

10. The electrical interconnect of claim 1, wherein the porous scaffold comprises an open pore foam, sponge, woolen material, or 3D printed open pore scaffolding.

11. The electrical interconnect of claim 1, wherein the unfilled porous scaffold has a porosity of about 75-97% or more and an average pore size of approximately 0.01-2.5 mm.

12. The electrical interconnect of claim 1, wherein the unfilled porous scaffold has a surface density of about 350-1500 g/m².

13. The electrical interconnect of claim 1, wherein the unfilled porous scaffold comprises a metal or alloy, carbon-based material, or ceramic material.

14. The electrical interconnect of claim 13, wherein the metal or metal alloy comprises nickel (Ni), aluminum (Al), copper (Cu) or carbon (C).

15. The electrical interconnect of claim 1, wherein the PCM comprises a metal or metal alloy, wax or sugar alcohol.

16. The electrical interconnect of claim 15, wherein the metal or metal alloy comprises gallium (Ga), indium (In), tin (Sn), bismuth (Bi), cadmium (Cd), lead (Pb), zinc (Zn) or antimony (Sb).

17. The electrical interconnect of claim 1, further comprising:
a first electrode contact electrically connected to the circuit; and
a second electrode contact electrically connected to the PCM-filled porous scaffold.

18. The electrical interconnect of claim 17, further comprising electrically conductive wires or traces which connect to the first and second electrode contacts.

19. The electrical interconnect of claim 1, wherein the electrical conductivity of the PCM-filled porous scaffold is 1-1000 S/cm or more.

20. A thermal buffering electrical interconnect comprising:
a first electrode contact;
an electrical circuit which generates heat electrically connected to the first contact;
a composite electrically connected to the circuit and comprising an electrically conductive porous scaffold having an electrically conductive phase change material (PCM) at least partially filling the porous space of the scaffold, wherein the melting point of the metal PCM is selected to be below the maximum safe operating temperature of the circuit; and
a second electrode contact electrically connected to the metal-filled porous scaffold.
